(19) United States
(12) Patent Application Publication
(10) Pub. No.: US 2026/0254323 A1
(43) Pub. Date: Aug. 27, 2026

(54) ROTATION SPEED DETECTION APPARATUS, ROTATION SPEED DETECTION SYSTEM, ROTATION SPEED CALCULATION APPARATUS, AND ROTATION SPEED DETECTION METHOD

(71) Applicant: Asahi Kasei Microdevices Corporation, Tokyo (JP)

(72) Inventors: Kazunori TANABE, Tokyo (JP); Shiko MIYASHITA, Tokyo (JP); Taiki NAKANISHI, Tokyo (JP)

(21) Appl. No.: 19/422,458

(22) Filed: Dec. 17, 2025

(30) Foreign Application Priority Data
Dec. 26, 2024 (JP) 2024-230147

(51) Int. Cl. H02K 11/215; G01R 33/00; H02K 11/00

(52) U.S. Cl. CPC H02K 11/215; G01R 33/0005; H02K 11/0094; H02K 2213/03

(57) ABSTRACT

Provided is a rotation speed detection apparatus comprising: a magnetic wire outputs a pulse of a polarity depending on a change in a direction of a magnetic field in accordance with a rotation operation of a rotator; a magnet polarity determination unit that determines a polarity of a magnet that is included in the rotator; and a calculation unit that calculates a count value by counting a segment in a circumferential direction of the rotator, wherein the calculation unit calculates the count value, based on a polarity of the magnet of the rotator acquired last time, a polarity of the pulse of this time, and a polarity of the magnet of the rotator at a time the pulse of this time is generated, and without using a polarity of the pulse of last time.

The contents of the following patent application(s) are incorporated herein by reference:
NO. 2024-230147 filed in JP on Dec. 26, 2024.

### BACKGROUND

### 1. Technical Field

The present invention relates to a rotation speed detection apparatus, a rotation speed detection system, a rotation speed calculation apparatus, and a rotation speed detection method.

### 2. Related Art

Conventionally, a multiple rotation angle detection apparatus using a power generation sensor is known (for example, see Patent document 1).
Patent document 1: Japanese Patent Application Publication No. 2024-106245

### BRIEF DESCRIPTION OF THE DRAWINGS

FIG. 1 shows a rotation speed detection system 200 in an example.

FIG. 2 shows an arrangement example of a magnetic wire 10, a magnet polarity determination unit 14, and a magnet 20.

FIG. 3A illustrates the polarity of a pulse that is output by the magnetic wire 10, and the polarity of the magnet 20 that is determined by the magnet polarity determination unit 14.

FIG. 3B illustrates a relationship between the polarity of the pulse, the polarity of the magnet 20, and a count value.

FIG. 4A illustrates the polarity of a pulse that is output by the magnetic wire 10 and the polarity of the magnet 20 that is determined by the magnet polarity determination unit 14 in Patent document 1.

FIG. 4B illustrates a relationship between the polarity of the pulse, the polarity of the magnet 20, and the count value in Patent document 1.

FIG. 5A illustrates the polarity of the pulse and the polarity of the magnet 20 in a case in which the arrangement of the magnetic wire 10 and the magnet polarity determination unit 14 in Patent document 1 is the same as that of FIG. 3A.

FIG. 5B illustrates a relationship between the polarity of the pulse, the polarity of the magnet 20, and the count value of FIG. 5A.

FIG. 6A illustrates the polarity of the pulse and the polarity of the magnet 20 in a case in which the arrangement of the magnetic wire 10 and the magnet polarity determination unit 14 in the example is different.

FIG. 6B illustrates the relationship between the polarity of the pulse, the polarity of the magnet 20, and the count value in FIG. 6A.

FIG. 7 is a flowchart showing an example of a rotation speed detection method of a rotator 30.

FIG. 8A illustrates a relative position of the magnet polarity determination unit 14 relative to the magnetic wire 10.

FIG. 8B is another figure describing the relative position of the magnet polarity determination unit 14 relative to the magnetic wire 10.

FIG. 9 is a perspective view showing an example of the arrangement of the magnet 20, the magnet polarity determination unit 14, and the magnetic wire 10.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention. In the present specification, the same portion in each figure is denoted with the same reference numeral, and the description thereof may be omitted. In addition, some components may not be illustrated for the convenience of the description.

In the present specification, technical matters may be described using orthogonal coordinate axes of an X axis, a Y axis, and a Z axis. The orthogonal coordinate axes merely specify relative positions of components, and do not limit a specific direction. For example, the Z axis direction is not limited to indicating the height direction with respect to the ground. Note that a +Z axis direction and a-Z axis direction are directions opposite to each other. When the Z axis direction is described without describing the signs, it means that the direction is parallel to the +Z axis and the-Z axis.

In the present specification, being referred to as “same”, “equal”, “parallel” or “perpendicular” may also include a case in which there is an error due to a manufacturing variation and the like. The error is, for example, within 10%.

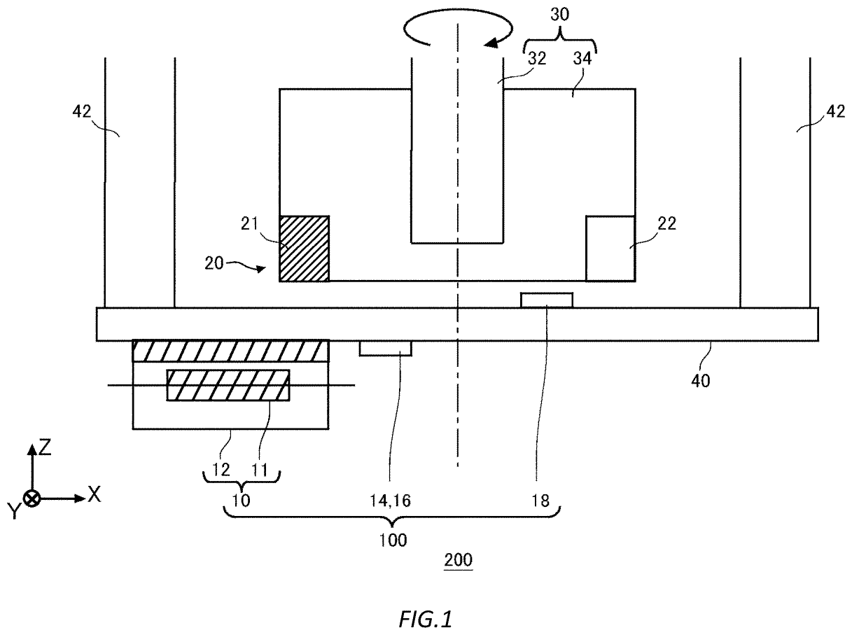

FIG. 1 shows a rotation speed detection system 200 in an example. FIG. 1 shows a cross-section of the rotation speed detection system 200. The rotation speed detection system 200 includes a rotator 30, a rotation speed detection apparatus 100, a support base 40, and a support member 42. The rotation speed detection apparatus 100 senses the rotation of the rotator 30. The rotation speed detection apparatus 100 senses at least one of the rotation speed or the rotational direction of the rotator 30. The rotation speed detection system 200 may further include a sensor for a single turn that detects the rotation angle within one rotation cycle of the rotator 30.

The rotator 30 of the present example has a rotation axis 32 and an attachment portion 34. As an example, the rotation axis 32 is a rotation axis of a motor, or an axis of a stage. In FIG. 1, the rotation axis 32 extends in a Z axis direction. The attachment portion 34 is attached to the rotation axis 32. In FIG. 1, the rotator 30 rotates in the XY plane with the Z axis direction as an axial direction.

The attachment portion 34 has a magnet 20. The magnet 20 is a multipolar magnet. The magnet 20 has two or more first polar portions 21 and two or more second polar portions 22. One of the first polar portion 21 and the second polar portion 22 is an N pole, and another one is an S pole. In FIG. 1 and subsequent drawings, the first polar portion 21 is denoted with hatching.

The rotator 30 is magnetized to four or more poles along with the rotational direction. That the rotator 30 is magnetized means that the rotator 30 itself may be magnetized or means that the magnet 20 of four or more poles may be attached to the rotator 30 as in the present example. The first polar portion 21 and the second polar portion 22 of the present example are arranged alternately along with the rotational direction of the rotator 30. The rotational direction is a direction by which the rotator 30 is rotating when viewing from the axial direction of the rotator 30 (Z axis direction) and a circumferential direction of a circle around a rotation axis 32. For example, the first polar portion 21 is arranged adjacent to the second polar portion 22 shown in FIG. 1 in the circumferential direction, and the second polar portion 22 is arranged adjacent to the first polar portion 21 in the circumferential direction. Viewed from the Z axis direction, two or more of the first polar portions 21 and the second polar portion 22 may be arranged respectively along with the circumferential direction, or three or more may be arranged.

The magnet 20 may have a columnar shape, or may have a cavity provided in a direction that is perpendicular to the bottom surface of the cylinder. That is, the magnet 20 may be a cylindrical ring magnet. A cylindrical cavity portion of the magnet 20 of the present example overlaps with the rotation axis 32 in the Z axis direction. The magnet 20 rotates together with the rotator 30.

The rotation speed detection apparatus 100 includes a magnetic wire 10, a magnet polarity determination unit 14, and a calculation unit 16. The rotation speed detection apparatus 100 may further include a storage unit 18. In FIG. 1, the XZ cross-section of the rotation speed detection apparatus 100 and the rotator 30 is shown. Note that some components may not exist in the same cross-section, in FIG. 1, each component is shown in the same cross-section for description.

The magnetic wire 10, the magnet polarity determination unit 14, the calculation unit 16, and the storage unit 18 are attached to the support base 40. The support base 40 is attached to the support member 42, and arranged to face the rotator 30 in the Z axis direction. The shape of each of the rotator 30, the magnet 20, the support base 40, and the support member 42 may be a circular shape around the rotation axis 32 in the XY plane. In the present example, the support base 40 does not rotate.

The magnetic wire 10 may be a wire having layers of materials with different magnetic sensitivity stacked, that is, a Wiegand wire. The magnetic wire 10 has a first material 11 and a second material 12. By covering with the second material 12 around the first material 11, a double-layer structure wire is formed. A coil may be wound around the magnetic wire 10.

Each of the first material 11 and the second material 12 has a different magnetic sensitivity. In the present example, the first material 11 is hard magnetic, and the second material 12 is soft magnetic. When a strength of an external magnetic field changes gradually, only the orientation of magnetization of the second material 12 having a high magnetic sensitivity at the strength of a magnetic field changes. At that time, a pulse is generated on the coil that is wound around the magnetic wire 10. The pulse may be a voltage pulse, may be a current pulse, or may be both. Note that the magnetic sensitivity of the first material 11 of the magnetic wire 10 may be higher than the magnetic sensitivity of the second material 12.

When the rotator 30 rotates, the magnet 20 relatively rotates in relation to the magnetic wire 10, and therefore, the strength and the direction of the magnetic field applied to the magnetic wire 10 from the magnet 20 are changed. The magnetic wire 10 outputs a pulse of a polarity that depends on the change in the direction of the magnetic field. The magnetic wire 10 may output a pulse of a polarity that depends on the change in the strength and the direction of the magnetic field. There are two types of polarity of the pulse, depending on the direction in which the second material 12 is magnetized. In the present specification, the polarity of the pulse is represented with positive (+) and negative (−). That is, the magnetic wire 10 generates a pulse by the rotation of the rotator 30. In other words, an alternating magnetic field is formed by the magnet 20 two times or more per one rotation, then this alternating magnetic field is applied in the longitudinal direction of the magnetic wire 10, and thereby the magnetic wire 10 outputs a pulse depending on the change of the direction of the magnetic field.

The magnet polarity determination unit 14 determines the polarity of the magnet 20 of the rotator 30. The magnet polarity determination unit 14 may be a magnetic sensor. The magnet polarity determination unit 14 of the present example is a Hall element. Note that the magnet polarity determination unit 14 is not limited to the magnetic sensor as long as the polarity of the magnet 20 of the rotator 30 can be determined. For example, the polarity of the magnet 20 may be determined by forming a cutout on the rotator 30, which depends on the polarity of the magnet 20, and then measuring the cutout by using an optical sensor.

The calculation unit 16 is a rotation speed calculation apparatus that calculates a count value representing the rotation speed of the rotator 30. The calculation unit 16 calculates the count value based on the output of the magnetic wire 10 and the magnet polarity determination unit 14. A calculation method of the count value will be described below. The calculation unit 16 may read information from the storage unit 18 for calculating the count value. The calculation unit 16 outputs the calculated count value to the storage unit 18. The calculation unit 16 and the magnet polarity determination unit 14 of the present example are configured by an IC with the Hall sensor incorporated thereon. Note that the calculation unit 16 may be provided separately from the magnet polarity determination unit 14. The calculation unit 16 may be a counter circuit that counts the count value.

The storage unit 18 integrates the count value calculated by the calculation unit 16 to store the integrated count value as an integrated value. The storage unit 18 may be a non-volatile memory with a low power consumption, for example, FRAM (registered trademark) or the like. Although not illustrated, the magnetic wire 10, the magnet polarity determination unit 14, the calculation unit 16, and the storage unit 18 may be coupled by wiring.

The magnet polarity determination unit 14, the calculation unit 16, and the storage unit 18 may be operated by the electrical power of a pulse output by the magnetic wire 10. In this way, the rotation speed of the rotator 30 can be calculated and maintained even if a power source is not supplied from a battery or the like. The magnet polarity determination unit 14 may determine the polarity of the magnet 20 of the rotator 30 every time a pulse is generated. The calculation unit 16 may calculate the count value by reading information from the storage unit 18 every time the pulse is generated, and may write the calculated count value or the like to the storage unit 18. An external capacitor may be provided to the calculation unit 16 to charge the electrical power of the pulse of the magnetic wire 10. In addition, the calculation unit 16 may rectify the pulse of the magnetic wire 10.

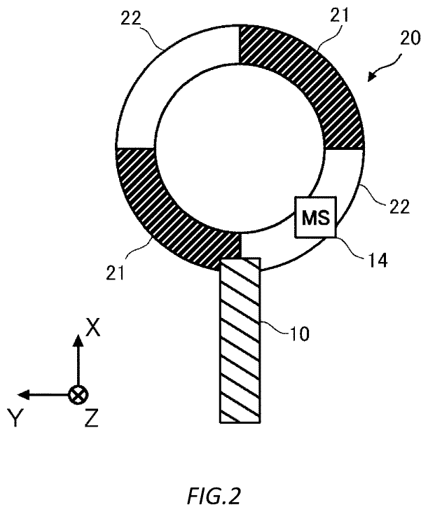

FIG. 2 shows an arrangement example of a magnetic wire 10, a magnet polarity determination unit 14, and a magnet 20. FIG. 2 shows an arrangement example in a case in which the magnetic wire 10, the magnet polarity determination unit 14, and the magnet 20 are viewed from the negative side in the Z axis direction in FIG. 1. In FIG. 2, another component will not be illustrated for description. In addition, the entire magnetic wire 10 is denoted with a rough hatching.

The magnet 20 of the present example has two first polar portions 21 and two second polar portions 22 on the circumference in the XY plane. The magnet 20 of the present example has a first polar portion 21 and a second polar portion 22 every 90 degrees in the circumferential direction.

The magnetic wire 10 of the present example may be extended in a predetermined direction. For example, an extending direction of the magnetic wire 10 with a columnar shape is a direction that is perpendicular to a circular cross-section. In FIG. 2, the magnetic wire 10 is extended in the X axis direction. In the present specification, the direction of the magnetic wire 10 may be the extending direction of the magnetic wire 10.

The magnetic wire 10 may be arranged to output a pulse when the boundary of the magnetization of the rotator 30 is deviated from an opposite position. For the present example, the boundary of the magnetization of the rotator 30 is the boundary between the first polar portion 21 and the second polar portion 22 of the magnet 20. The magnetic wire 10 may be extended in a direction that intersects with a tangential line of the rotator 30. Directions of the tangential line of the rotator 30 and the tangential line of the magnet 20 may match. The magnetic wire 10 of the present example is orthogonal to the tangential line of the magnet 20. By such an arrangement, as described below, the magnetic wire 10 outputs a pulse when the boundary of the magnetization of the rotator 30 is deviated from an opposite position.

The magnet polarity determination unit 14 is arranged at a predetermined relative position in relation to the magnetic wire 10. The magnet polarity determination unit 14 of the present example is arranged at a position 45 degrees from the magnetic wire 10 with the center of the circle of the magnet 20 being as a reference. At the position, the magnetic wire 10 may be arranged to overlap with the magnet 20 in the Z axis direction. The magnet polarity determination unit 14 determines the polarity (an N pole, an S pole) of the magnet 20 at the position.

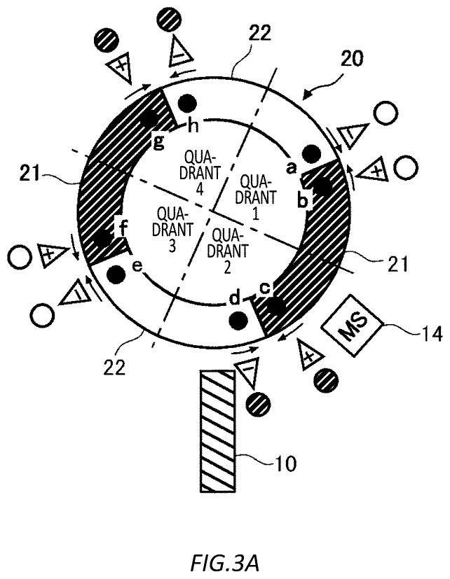

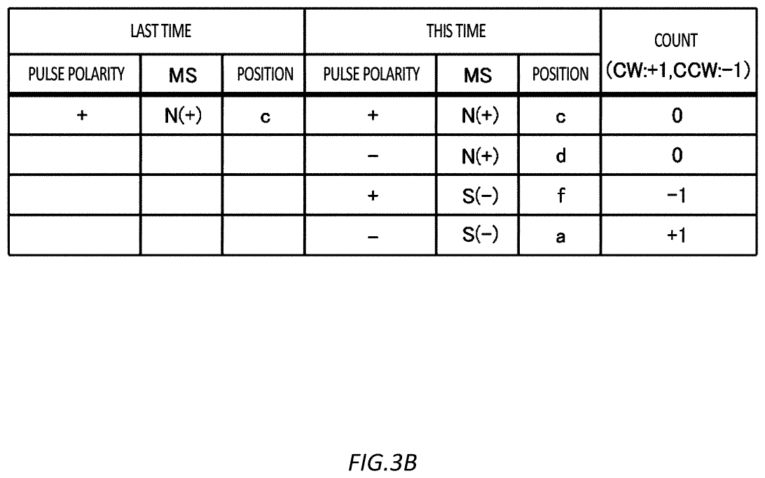

FIG. 3A illustrates the polarity of a pulse that is output by the magnetic wire 10, and the polarity of the magnet 20 that is determined by the magnet polarity determination unit 14. FIG. 3B illustrates a relationship between the polarity of the pulse, the polarity of the magnet 20, and a count value. In the present example, the first polar portion 21 of the magnet 20 is the N pole, and the second polar portion 22 is the S pole.

In the present example, the magnetic wire 10 is arranged in a direction that intersects with the tangential line of the magnet 20, the magnetic wire 10 outputs a pulse when the magnet 20 rotates, and the boundary of the first polar portion 21 and the second polar portion 22 is deviated from a position opposite to the magnetic wire 10. Points a to h indicated with black circles in the figure are points, the boundary of which is deviated from the position opposite to the magnetic wire 10, and the magnetic wire 10 outputs a pulse when each point comes to the position opposite to the magnetic wire 10.

The arrow shown outside of each point represents that the pulse is output when the magnet 20 is rotated in the orientation of the arrow. The triangle shown further outside than the arrow represents the polarity of the pulse. In the present example, the pulse with a positive polarity is represented with an inward triangle, and the pulse with a negative polarity is represented with an outward triangle.

The circle mark shown further outside than the triangle shows the polarity of the magnet 20 sensed by the magnet polarity determination unit 14 at the time of the pulse generation. The hatched circle mark represents the first polar portion 21, and the circle mark without hatching represents the second polar portion 22. The magnet polarity determination unit 14 of the present example senses the polarity of the magnet 20 in a portion opposite to the magnet polarity determination unit 14 at the time of the pulse generation.

As an example, a case in which the magnet 20 is rotated in a clockwise manner from a state of FIG. 3A is described. Even if the rotation proceeds, and the point d is rotated to the position opposite to the magnetic wire 10, the pulse is not output since the point d is a counter-clockwise arrow. Subsequently, when the rotation further proceeds, and the point c is rotated to the position opposite to the magnetic wire 10, the pulse is output, since the point c is a clockwise arrow. The polarity at that time is positive. This is a pulse generated by the magnetic wire 10 as a result of magnetizing only the second material 12 in an opposite direction by the magnetic field of the first polar portion 21 after the first material 11 and the second material 12 of the magnetic wire 10 are magnetized in the same direction by the magnetic field of the second polar portion 22. In addition, the polarity of the magnet 20 sensed at that time by the magnet polarity determination unit 14 is the first polar portion 21 (the N pole). In the table of FIG. 3B, in the section “last time”, the polarity of the pulse in a case of the position c is indicated as positive, and the polarity of the magnet 20 (MS) is indicated as N(+). In the present example, when calculating the count value, the N pole is treated as +.

There are four positions: point c, point d, point f, and point a, at which the pulse may be generated after the pulse is generated at the point c of the last time. In the section “this time” of FIG. 3B shows each of the points in each row in this order. First, a case in which the pulse at this time is generated at the point c is described. In this case, the magnet 20 starts a counter-rotation (counter-clockwise) with hardly being rotated in a clockwise manner after the pulse is generated at the point c of the last time. At this time, the first material 11 of the magnetic wire 10 is not magnetized by the magnetic field of the first polar portion 21 of the magnet 20. Therefore, the pulse is not generated even if the magnet 20 is rotated in a counter-clockwise manner and the point d is rotated to the position opposite to the magnetic wire 10. In this manner, a phenomenon in which the pulse is not generated at a position at which the pulse is inherently generated is referred to as a “pulse omission”. Subsequently, if the magnet 20 is rotated in a clockwise manner again and the point c is rotated to the position opposite to the magnetic wire 10, the pulse is generated. The polarity of the pulse at that time is positive, the polarity of the magnet 20 (MS) is N(+), and these are shown in the row of the point c in the “this time” section in FIG. 3B. Both the pulse polarity and the polarity of the magnet 20 are the same as those in the case of the point c of the last time. Note that “last time” in the present specification represents when the pulse is generated last time, and “this time” may represent when the pulse is generated this time.

Then, a case in which the pulse is generated this time at the point d is described. In this case, the magnet 20 is rotated in a clockwise manner until the first material 11 of the magnetic wire 10 is magnetized by the magnetic field of the first polar portion 21 after the pulse is generated at the point c of the last time. Subsequently, when the rotation manner is turned into a counter-clockwise manner so that the point d is rotated to the position opposite to the magnetic wire 10, the pulse is generated. The polarity of the pulse at this time is negative, and the polarity of the magnet 20 (MS) is N(+).

Then, a case in which the pulse is generated this time at the point f is described. This case is similar to the case of the point c in that the magnet 20 is rotated in a counter-clockwise manner, the pulse omission is generated, and the pulse is not generated at the point d. Subsequently, if the magnet 20 continues to rotate in a counter-clockwise manner and the point f is rotated to the position opposite to the magnetic wire 10, the pulse is generated. The polarity of the pulse at that time is positive, and the polarity of the magnet 20 (MS) is S(−).

Then, a case in which the pulse is generated this time at the point a is described. In this case, the magnet 20 continues to rotate in a clockwise manner after the pulse is generated at the point c of the last time. Then, if the point a is rotated to the position opposite to the magnetic wire 10, the pulse is generated. The polarity of the pulse at that time is negative, and the polarity of the magnet 20 (MS) is S(−).

Subsequently, the calculation of the count value will be described. The count value is a value representing the rotation speed of the rotator 30. In the present example, the count value 4 corresponds to one rotation. The count value is indicated in the rightmost column in the table of FIG. 3B. In the count value of the present example, clockwise (CW) is positive (+), and counter-clockwise (CCW) is negative (−). In other words, as shown in FIG. 3A, the rotator 30 or the magnet 20 is defined to have, upon setting a rotating coordinate system around a rotation axis thereof, four segments (quadrants) divided by two axes that pass through a rotation axis and are orthogonal to the rotation axis, and the count value decreases or increases depending on the change in the segments facing the magnetic wire 10 due to the rotation. The determination between increasing and subtracting the count value is further determined by the combination with the result of sensing of the magnet polarity determination unit 14. Note that in addition to the foregoing definition, the segment may be defined as a region having a predetermined angular width in the rotational direction around the rotation axis, for example. In other words, when one rotation is made up of four count values, a region corresponding to an angular width of 90 degrees in the rotational direction may be provided as a segment, for example. A segment facing the magnetic wire 10 is one segment whose distance to a placement position of the magnetic wire 10 is the shortest among a plurality of segments included in the rotator 30, and changes depending on the rotation operation.

In a case where the pulse generation position of the last time is the point c and the pulse generation position of this time is the point c, the count value is 0. This corresponds to that the pulse is generated in the quadrant 2 both this time and last time in FIG. 3A. In a case where the pulse generation position of the last time is the point c and the pulse generation position of this time is the point d, the count value is 0. This also corresponds to that the pulse is generated in the quadrant 2 both this time and last time in FIG. 3A.

In a case where the pulse generation position of the last time is the point c and the pulse generation position of this time is the point f, the count value is −1. This corresponds to that the pulse of the last time is generated in the quadrant 2 and the pulse of this time is generated in the quadrant 3 in FIG. 3A. In a case where the pulse generation position of the last time is the point c and the pulse generation position of this time is the point a, the count value is +1. This corresponds to that the pulse of the last time is generated in the quadrant 2 and the pulse of this time is generated in the quadrant 1 in FIG. 3A.

The calculation of the count value shown in FIG. 3B is an example, and the method can be summarized as follows. The calculation unit 16 calculates the count value based on the polarity of the magnet 20 of the last time, the polarity of the pulse of this time, and the polarity of the magnet 20 of this time. In addition, the calculation unit 16 calculates the count value without using the polarity of the pulse of the last time. In other words, the calculation unit 16 calculates the count value by counting the segments in a circumferential direction (herein, 4 segments configuration) of the rotator 30, depending on the rotation of the rotator 30 having the magnet 20 installed thereon. The description will be shown more specifically as follows. When an alternating magnetic field formed by rotating the magnet 20 included in the rotator 30 is applied to the magnetic wire 10, a pulse is generated depending on a change in the direction of the magnetic field. Then, the magnet polarity determination unit 14 determines the polarity of the magnet 20 at a predetermined relative position in relation to the magnetic wire 10 in response to the generation of the pulse. This operation may be considered as counting the number of times that a segment facing the magnetic wire 10 is changed into an adjacent another segment due to the rotation operation of the rotator 30, for a plurality of segments virtually defined as a region having a predetermined angular width over the circumferential direction of the rotator 30.

The calculation unit 16 may differentiate, depending on whether or not the polarity of the magnet 20 of the last time and the polarity of the magnet 20 of this time match, the count value for at least one polarity of the pulse of this time. In the example shown in FIG. 3B, when the polarity of the magnet 20 of the last time and the polarity of the magnet 20 of this time match (the point c and the point d of “this time”), the count value is the same (count value 0) regardless of the polarity of the pulse. When the polarity of the magnet 20 of the last time and the polarity of the magnet 20 of this time are different from each other (the point f and the point a of “this time”), the count value is differentiated to be +1 and −1 for the polarity of the pulse.

When the polarity of the magnet 20 of the last time and the polarity of the magnet 20 of this time are the same (the point c and the point d of “this time”), the calculation unit 16 may output the count value at which the integrated value is maintained. In FIG. 3B, the count value is 0. When the polarity of the magnet 20 of the last time and the polarity of the magnet 20 of this time are different from each other (the point f and the point a of “this time”), the calculation unit 16 may output the count value at which the integrated value is decreased or increased. In FIG. 3B, the count value is +1 or −1.

The calculation unit 16 may differentiate the sign of the count value depending on whether or not the polarity of the magnet 20 of this time and the polarity of the pulse of this time match. In FIG. 3B, when the polarity of the magnet 20 of the last time and the polarity of the magnet 20 of this time is different from each other (the point f and the point a of “this time”), if the polarity of the magnet 20 of this time and the polarity of the pulse of this time match (point a), the sign is negative, and if the polarity of the magnet 20 of this time and the polarity of the pulse of this time is different from each other (point f), the sign is positive. In this case, the absolute value of the count value may be equal. In FIG. 3B, if this time is the point a, the count value is +1, if this time is the point f, the count value is −1. That is, the absolute value is 1.

As described above, the calculation unit 16 calculates the count value without using the polarity of the pulse of the last time. That is, in the calculation of either of the above-described count values, the count value is calculated without using the polarity of the pulse of the last time. Thereby, upon calculating the count value, information for reference can be reduced.

The calculation unit 16 may read the polarity of the magnet 20 of the last time from the storage unit 18 during the calculation of the count value. The calculation unit 16 may not read the polarity of the pulse of the last time from the storage unit 18 during the calculation of the count value. The calculation unit 16 may calculate the count value based on only the polarity of the magnet 20 of the last time, the polarity of the pulse of this time, and the polarity of the magnet 20 of this time.

The calculation unit 16 may write the calculated count value to the storage unit 18. The calculation unit 16 may write information of the polarity of the magnet 20 of this time to the storage unit 18. Thereby, at the time of next pulse generation, the polarity can be read as the polarity of the magnet 20 of the last time. The calculation unit 16 may not write information of the polarity of the pulse of this time to the storage unit 18. The storage unit 18 may store the information of the polarity of the magnet 20. The storage unit 18 may not store the information of the polarity of the pulse.

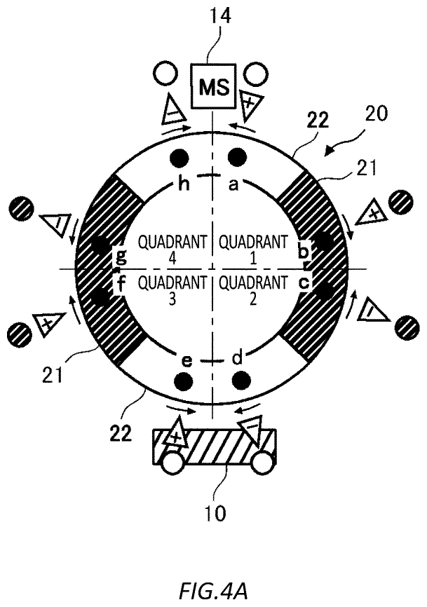

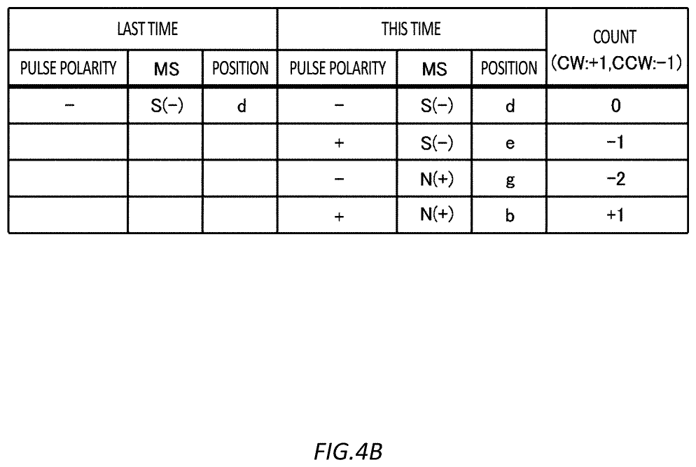

FIG. 4A illustrates the polarity of a pulse that is output by the magnetic wire 10 and the polarity of the magnet 20 that is determined by the magnet polarity determination unit 14 in Patent document 1. FIG. 4B illustrates a relationship between the polarity of the pulse, the polarity of the magnet 20, and the count value in Patent document 1. In FIG. 1, FIG. 2A to 2C of Patent document 1, shown are a power generation sensor 20 arranged in an orientation that is parallel to a tangential line of a magnetic field source 50 that is a four-pole magnetized magnet, and a sensor element MS that is arranged to detect the polarity of a magnetic pole that is opposite to the central portion of the power generation sensor 20 (paragraph 0079). The arrangement of each component of Patent document 1, the polarity of the pulse to be generated, and the polarity of the magnet 20 are represented as shown in FIG. 4A by using the display of FIG. 3A of the present specification.

In FIG. 4A, since the magnetic wire 10 is arranged in an orientation parallel to the tangential line of the magnet 20, the pulse generation position is different from that of FIG. 3A. In addition, the magnet polarity determination unit 14 detects the polarity of the magnet 20 in a portion opposite to the magnetic wire 10.

Similar to the case in FIG. 3A, a case in which the magnet 20 is rotated in a clockwise manner from a state in FIG. 4A is described. As the rotation proceeds and the point d is rotated to a position opposite to the center of the magnetic wire 10, a pulse is output. At that time, the polarity is negative. In addition, the polarity of the magnet 20 sensed by the magnet polarity determination unit 14 at that time is the second polar portion 22. In the table of FIG. 4B, in the section “last time”, the polarity of the pulse in a case of the position d is indicated as negative, and the polarity of the magnet 20 (MS) is indicated as S(−).

There are four positions: point d, point e, point g, and point b, at which the pulse may be generated after the pulse is generated at the point d of the last time. In the section “this time” of FIG. 4B shows each of the points in each row in this order. First, a case in which the pulse at this time is generated at the point d is described. In this case, the magnet 20 starts a counter-rotation (counter-clockwise) after the pulse is generated at the point d of the last time. Then, a pulse omission is generated in the point e. Subsequently, if the magnet 20 is rotated in a clockwise manner again and the point d is rotated to the position opposite to the center of the magnetic wire 10, the pulse is generated. The polarity of the pulse at that time is negative, the polarity of the magnet 20 (MS) is S(−), and these are shown in the row of the point d in the “this time” section in FIG. 3B. Both the pulse polarity and the polarity of the magnet 20 are the same as those in the case of the point d of the last time.

Then, a case in which the pulse is generated this time at the point e is described. In this case, the magnet 20 is rotated in a clockwise manner until the first material 11 of the magnetic wire 10 is also magnetized after the pulse is generated at the point c of the last time. Subsequently, when the rotation manner is turned into a counter-clockwise manner so that the point e is rotated to the position opposite to the center of the magnetic wire 10, the pulse is generated. The polarity of the pulse at this time is positive, and the polarity of the magnet 20 (MS) is S(−).

Then, a case in which the pulse is generated this time at the point g is described. This case is similar to the case of the point d in that the magnet 20 is rotated in a counter-clockwise manner, the pulse omission is generated, and the pulse is not generated at the point e. Subsequently, if the magnet 20 continues to rotate in a counter-clockwise manner and the point g is rotated to the position opposite to the center of the magnetic wire 10, the pulse is generated. The polarity of the pulse at that time is negative, and the polarity of the magnet 20 (MS) is N(+).

Then, a case in which the pulse is generated this time at the point b is described. In this case, the magnet 20 continues to rotate in a clockwise manner after the pulse is generated at the point d of the last time. Then, if the point b is rotated to the position opposite to the center of the magnetic wire 10, the pulse is generated. The polarity of the pulse at that time is positive, and the polarity of the magnet 20 (MS) is N(+).

Subsequently, the calculation of the count value will be described. The manner of obtaining the count value is similar to that in the case of FIG. 3B. In a case where the pulse generation position of the last time is the point d and the pulse generation position of this time is the point d, the count value is 0. This corresponds to that the pulse is generated in the quadrant 2 both this time and last time in FIG. 4A. In a case where the pulse generation position of the last time is the point d and the pulse generation position of this time is the point e, the count value is −1. This corresponds to that the pulse of the last time is generated in the quadrant 2 and the pulse of this time is generated in the quadrant 3 in FIG. 4A.

In a case where the pulse generation position of the last time is the point d and the pulse generation position of this time is the point g, the count value is −2. This corresponds to that the pulse of the last time is generated in the quadrant 2 and the pulse of this time is generated in the quadrant 4 in FIG. 4A. In a case where the pulse generation position of the last time is the point d and the pulse generation position of this time is the point b, the count value is +1. This corresponds to that the pulse of the last time is generated in the quadrant 2 and the pulse of this time is generated in the quadrant 1 in FIG. 4A.

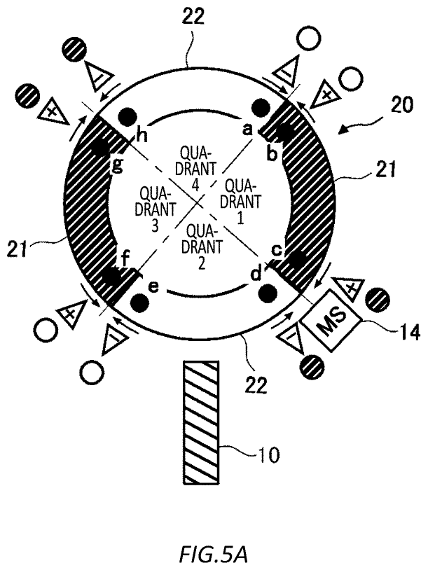

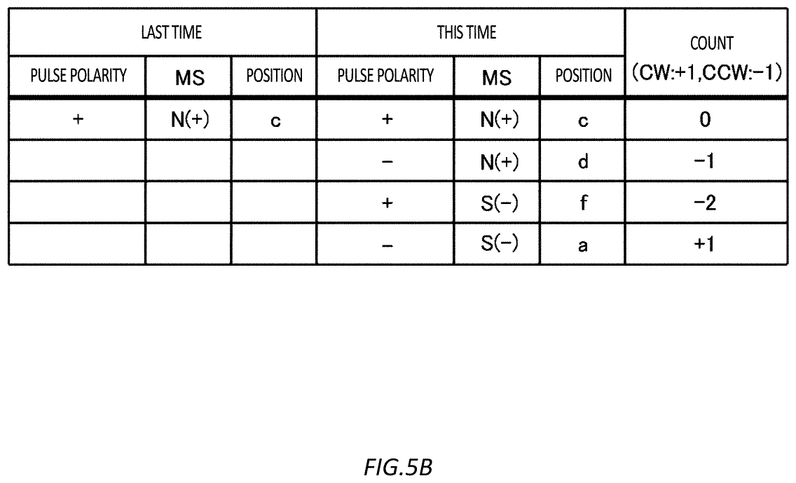

In FIG. 4B, there is-2 in the section of the count value. Considering another point other than the point d, the count value +2 exists, and therefore, in the example of FIG. 4A, an absolute value of 2 exists in the count value. In FIG. 5 of Patent document 1, the existence of +2 or −2 is shown. In addition, in FIG. 4B, it is impossible to calculate the count value without using the polarity of the pulse of the last time, and both the polarity of the magnet 20 of the last time and the polarity of the pulse of the last time are necessarily required to be used. In paragraphs 0104, 0105 of Patent document 1, it is described that the polarity of the pulse voltage of the last time and the sensor element state of the last time are used.

In the rotation speed detection apparatus 100 of the present embodiment, the count value is calculated without using the polarity of the pulse of the last time, and therefore, there is little information for reference. In addition, when an absolute value of 2 exists in the count value, writing to the storage unit 18 may have to be performed twice. In the rotation speed detection apparatus 100 of the present embodiment, the absolute value of the count value is 1, and therefore, the writing to the storage unit 18 is necessarily completed at once.

FIG. 5A illustrates the polarity of the pulse and the polarity of the magnet 20 in a case in which the arrangement of the magnetic wire 10 and the magnet polarity determination unit 14 in Patent document 1 is the same as that of FIG. 3A. FIG. 5B illustrates a relationship between the polarity of the pulse, the polarity of the magnet 20, and the count value of FIG. 5A.

Iin FIG. 5A, the magnetic wire 10 is arranged in a direction orthogonal to the tangential line of the magnet 20, and the magnet polarity determination unit 14 is arranged at a position 45 degrees from the magnetic wire 10 around a rotation axis. In FIG. 5A and FIG. 5B, detailed descriptions of each point will be omitted.

In FIG. 5B, there is 2 in the absolute value of the count value. This is because the count value is calculated using the polarity of the pulse as a reference in Patent document 1. In Patent document 1, according to paragraphs 0099 and 0100, the count value is +1 or −1 if the polarity of the pulse is different. That the count value is changed means that the quadrant (segment) is changed. Therefore, in FIG. 5B, for example, there is a boundary of the quadrant between the point c and the point d, each having a different polarity of the pulse. As a result, when the pulse is generated at the point d after the pulse is generated at the point c, the count value is −1. In addition, when a pulse omission is generated at the point d after the pulse is generated at the point c, and the next pulse is generated at the point f, the count value is −2. Thus, variations of the count value are increased to four types (0, −1,−2, +1), and both the polarity of the pulse of the last time and the polarity of the magnet 20 of the last time are required to be used for determining the count value.

In the present embodiment, the count value is calculated using the polarity of the magnet 20 as a reference. That is, the absolute value of the count value is 1 if the polarity of the magnet 20 is changed, and the absolute value of the count value is 0 if the polarity of the magnet 20 is not changed. Therefore, when the pulse is generated at the point d after the pulse is generated at the point c, the count value is 0 (refer to FIG. 3B). In addition, even if the pulse omission is generated at the point d after the pulse is generated at the point c, and the next pulse is generated at the point f, the movement of the quadrant is one according to the change of the polarity of the magnet 20, and the count value is −1 (refer to FIG. 3B).

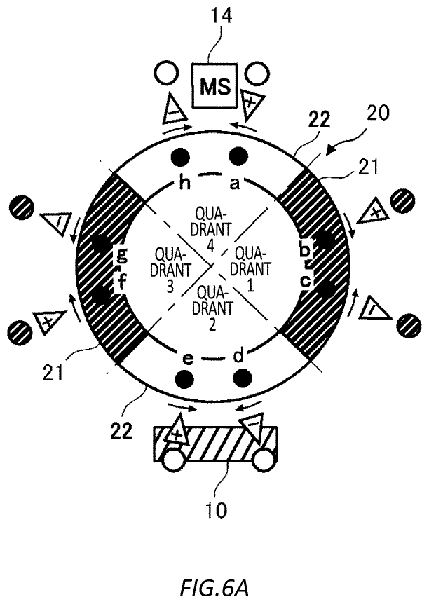

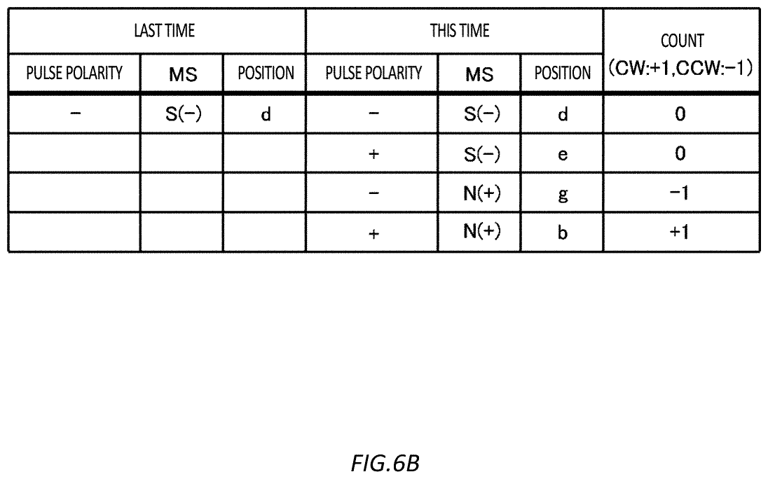

FIG. 6A illustrates the polarity of the pulse and the polarity of the magnet 20 in a case in which the arrangement of the magnetic wire 10 and the magnet polarity determination unit 14 in the example is different. FIG. 6B illustrates the relationship between the polarity of the pulse, the polarity of the magnet 20, and the count value in FIG. 6A. In FIG. 6A and FIG. 6B, detailed descriptions of each point will be also omitted.

In FIG. 6A, since the magnetic wire 10 is arranged in an orientation parallel to the tangential line of the magnet 20, the pulse generation position is the same position as that of FIG. 4A. In addition, the magnet polarity determination unit 14 detects the polarity of the magnet 20 in a portion opposite to the magnetic wire 10. Note that in the present example, the count value is calculated using the polarity of the magnet 20 as a reference. Therefore, the manner of dividing the quadrants is different from that of FIG. 4A.

From FIG. 6B, also in the present example, similar to FIG. 3B, it can be seen that the count value can be calculated without using the polarity of the pulse of the last time. In addition, the absolute value of the count value of the present example is 1. That is, regardless of the arrangement of the magnetic wire 10 and the magnet polarity determination unit 14, by calculating the count value using the polarity of the magnet 20 as a reference, the effect described above can be provided.

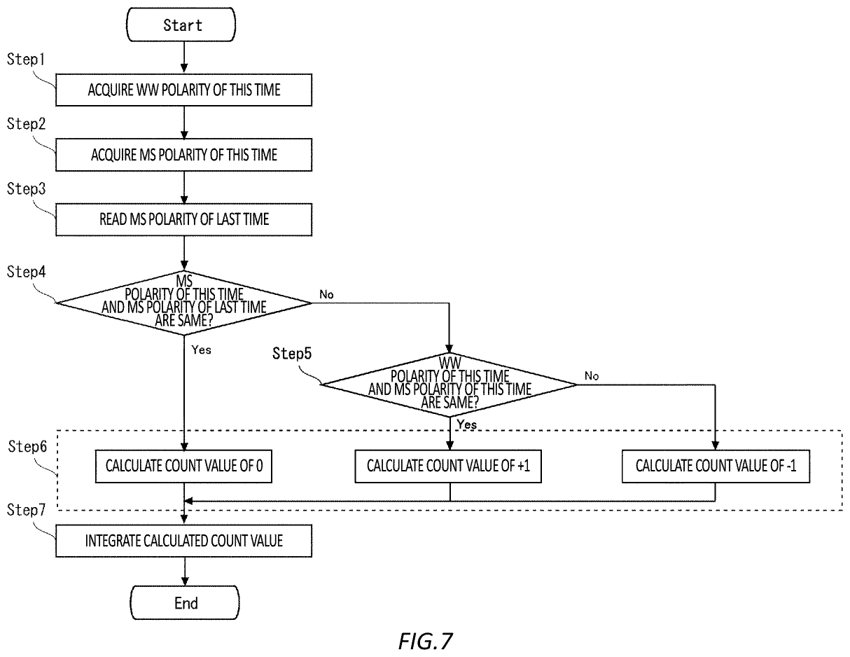

FIG. 7 is a flowchart showing an example of a rotation speed detection method of a rotator 30. In the rotation speed detection method, the count value described in FIG. 1 to FIG. 3B, FIG. 6A or FIG. 6B may be calculated. That is, in the rotation speed detection method, the count value may be calculated based on the polarity of the magnet 20 of the last time, the polarity of the pulse of this time, and the polarity of the magnet 20 of this time. In addition, in the rotation speed detection method, the count value may be calculated without using the polarity of the pulse of the last time. FIG. 7 is an example thereof.

In Step 1, the polarity of the pulse of the magnetic wire 10 of this time is acquired. The pulse may be a pulse of the magnetic wire 10 output depending on the change in the direction of the magnetic field applied from the rotator 30 magnetized to the four or more poles along with the rotational direction. In Step 2, the polarity of the magnet 20 of this time is acquired. The polarity of the magnet 20 may be the polarity of the magnet 20 of the rotator 30 at a predetermined relative position in relation to the magnetic wire 10. Step 1 and Step 2 may be performed in the calculation unit 16 of FIG. 1.

In Step 3, the polarity of the magnet 20 of the last time is read. In Step 3, the calculation unit 16 may read the polarity of the magnet 20 of the last time from the storage unit 18. Note that the order of Steps 1 to 3 may be different from that of FIG. 7.

In Step 4, whether or not the polarity of the magnet 20 of this time and the polarity of the magnet 20 of the last time match is determined. When the polarity of the magnet 20 of this time and the polarity of the magnet 20 of the last time match (Yes), the count value with which the integrated value of the count value is maintained may be calculated. In the present example, the method proceeds to Step 6 to calculate the count value of 0.

When the polarity of the magnet 20 of this time and the polarity of the magnet 20 of the last time do not match (No), the count value that reduces or increases the integrated value may be output. In the case of the present example, the method proceeds to Step 5 to determine whether or not the pulse polarity of this time and the polarity of the magnet 20 of this time match. When the pulse polarity of this time and the polarity of the magnet 20 of this time match (Yes), the count value of +1 is calculated in Step 6. When the pulse polarity of this time and the polarity of the magnet 20 of this time do not match (No), the count value of −1 is calculated in Step 6. Steps 4 to 6 may be performed in the calculation unit 16. In other words, if the calculation unit 16 is driven by the pulse to start the calculation of the count value, the calculation unit 16 senses, based on the polarity of the magnet 20 of the rotator 30 acquired last time, the polarity of the pulse of this time, and the polarity of the magnet 20 of the rotator 30 at a time the pulse of this time is generated, that another segment that is adjacent to a segment opposite to the magnetic wire 14 at a placement position of the magnetic wire 10 at the time of the pulse generation of last time is moved to face the placement position of the magnetic wire 10 at the time of the pulse generation of this time. More specifically, the calculation unit 16 determines that, at the time of the pulse generation of this time, if a segment opposite to the placement position of the magnetic wire 10 has reached its position by performing a rotation operation either in a clockwise manner or a counter-clockwise manner from the position in which it has been existed at the time of the pulse generation of the last time, and calculates the count value according to the determination result.

In Step 7, the calculated count value is integrated. The integration of the count value may be performed at the storage unit 18 by outputting the count value calculated by the calculation unit 16 to the storage unit 18. In addition, in Step 7, the polarity of the magnet 20 of this time may be saved. The calculation unit 16 may write the polarity of the magnet 20 of this time to the storage unit 18. In Step 7, the polarity of the pulse of this time may not be saved.

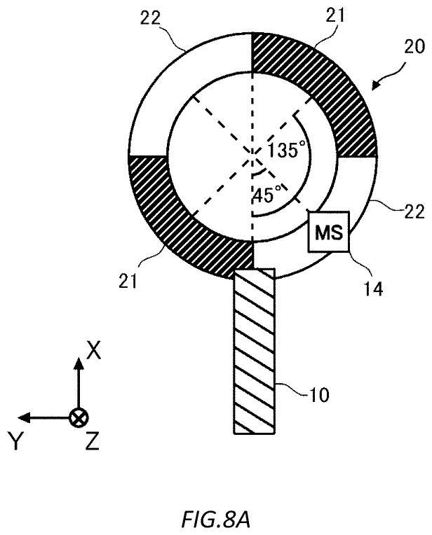

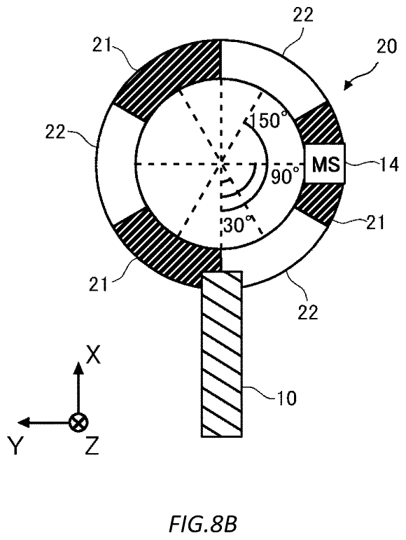

FIG. 8A illustrates a relative position of the magnet polarity determination unit 14 relative to the magnetic wire 10. The rotator 30 of the present example is magnetized to four poles. Note that in FIG. 8A, only inside the rotator 30 and the magnet 20 are shown. The magnetic wire 10 of the present example is extended in a direction that intersects with a tangential line of the rotator 30 in the rotational direction.

The magnet polarity determination unit 14 of the present example is a magnetic sensor. The magnet polarity determination unit 14 of the present example is arranged not to face any boundary of the magnetization of the rotator 30 when the magnetic wire 10 and the boundary of magnetization of the rotator 30 are arranged at a position to face each other. Also in the present example, the boundary of the magnetization of the rotator 30 is the boundary between the first polar portion 21 and the second polar portion 22 of the magnet 20. FIG. 8A shows a case in which the magnetic wire 10 and the boundary of the magnetization of the rotator 30 are arranged at opposite positions. In this way, the false positive of the magnet polarity determination unit 14 can be reduced. Not facing the boundary may mean that a boundary does not exist in a range within ±10 degrees around the magnet polarity determination unit 14 in the rotational direction. The boundary of the first polar portion 21 and the second polar portion 22 may be arranged at an equal angle interval in the rotational direction.

The magnet polarity determination unit 14 may be arranged to have the greatest distance from the boundary of the magnetization of the rotator 30 when the magnetic wire 10 and the boundary of the magnetization of the rotator 30 are arranged at opposite positions. The distance from the boundary may be the distance from a boundary that is the closest to the magnet polarity determination unit 14. As long as the boundary is arranged at an equal angle interval, there are two boundaries with equal distance from the magnet polarity determination unit 14. In the case of the present example, the magnet polarity determination unit 14 is arranged at a position 45 degrees or 135 degrees from the magnetic wire 10 around the rotation axis 32 of the rotator 30, and at this position, the distance from the boundary is the maximum. In this way, the false positive of the magnet polarity determination unit 14 can be reduced. Note that the above-described arrangement or the angle may have a width. The width may be ±10 degrees, ±5 degrees, or ±2 degrees.

FIG. 8B is another figure describing the relative position of the magnet polarity determination unit 14 relative to the magnetic wire 10. The rotator 30 of the present example is magnetized to six poles. Note that in FIG. 8B, only inside the rotator 30 and the magnet 20 are shown. The boundary of the first polar portion 21 and the second polar portion 22 of the present example are also arranged at an equal angle interval in the rotational direction. The magnetic wire 10 of the present example is also extended in a direction that intersects with a tangential line of the rotator 30 in the rotational direction. The magnet polarity determination unit 14 of the present example is also a magnetic sensor.

In the present example, when the magnetic wire 10 and the boundary of the magnetization of the rotator 30 are arranged at opposite positions, the position of the magnet polarity determination unit 14 at which the distance from the boundary of the magnetization of the rotator 30 is the greatest is a position 30 degrees, 90 degrees, or 150 degrees from the magnetic wire 10 around the rotation axis 32 of the rotator 30. The false positive of the magnet polarity determination unit 14 can be reduced by arranging the magnet polarity determination unit 14 at the above-described position. The above-described angle may have a width of ±5 degrees or ±2 degrees.

For generalizing the arrangement described above, refer to the following. That is, described is an arrangement of the magnet polarity determination unit 14 that has the greatest distance from the boundary of the magnetization of the rotator 30 when the magnetic wire 10 and the boundary of the magnetization of the rotator 30 are arranged in the opposite positions in a case in which the magnetic wire 10 is extended in a direction that intersects with the tangential line of the rotator 30 in the rotational direction. The rotator is magnetized to the n pole. n is an even number. n may be an even number of 4 or more, an even number of 6 or more, or an even number of 8 or more. In addition, the boundary of the magnetization of the rotator 30 is arranged at an equal angle interval in the rotational direction.

If the magnet polarity determination unit 14 is arranged at a position angle θₘ from the magnetic wire 10 around the rotation axis of the rotator 30 provided below, the distance from the boundary is the greatest.

$${θ}_{m} = 180 \times m / n$$

Note that m is any odd number less than n. The maximum value of the angle θₘ is 180 degrees. That is, the above-mentioned expression may be symmetrically used in a clockwise or a counter-clockwise manner using the magnetic wire 10 as a reference.

For example, when n =4, the angle θₘ is 45 degrees (m=1), or 135 degrees (m=3), to match the example in FIG. 8A. The angle θₘ may have a width. The width may be ±40/n degrees, ±20/n degrees, or ±8/n degrees. In addition, the boundary position of the magnetization of the rotator 30 may also have a width similar to that of the angle θₘ. In this manner, a movement sensing of the segment described above can be performed by installing the magnetic wire 10 and the magnet polarity determination unit 14, and setting each segment to include the boundary of the magnetization in a segment allocation for the rotator 30. This arrangement relationship and segment allocation allow sensing in both the case in which the segment change is generated for the pulse generation and the case in which the segment change is not generated. More specifically, if the pulse is generated upon the boundary of the magnetization passes the opposite position facing the magnetic wire 10 by the rotation of the rotator 30, it may be sensed that any segment is at that position. Furthermore, the magnet polarity determination unit 14 provided at a relative position described above specifies the polarity of the magnet 20 that is at a position opposite to the relative position described above. Then, that the segment opposite to the magnetic wire 10 is the same at both the last time and this time can be determined as long as the polarity of the magnet 20 and the polarity of the magnet 20 at the time of the last measurement match. In addition, that the segment change is generated can be sensed as long as the polarity of the magnet 20 and the polarity of the magnet 20 at the time of the last measurement are different from each other. Then, it can be determined, based on the combination of this information and the polarity of the pulse, that the segment change resulted from the rotation operation of either the clockwise or counter-clockwise manner.

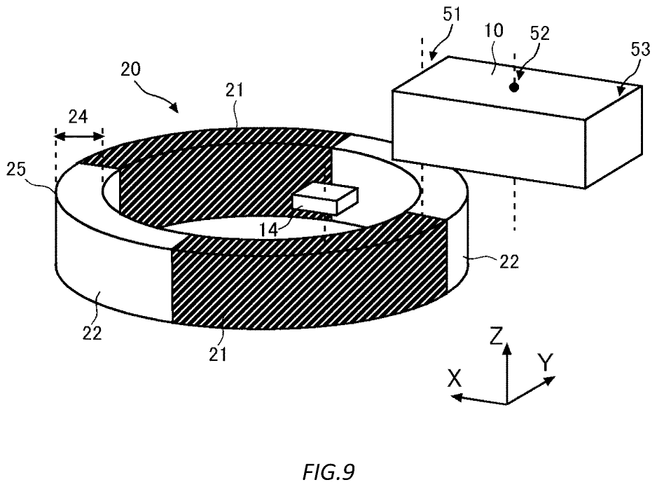

FIG. 9 is a perspective view showing an example of the arrangement of the magnet 20, the magnet polarity determination unit 14, and the magnetic wire 10. In the rotation speed detection system 200 described above, the magnet 20, the arrangement of the magnet polarity determination unit 14, and the magnetic wire 10 can be generalized as follows, for example. That is, the rotation speed detection system 200 has a magnet 20 magnetized to four or more poles along with the rotational direction as a rotation magnet. For the rotation of the magnet 20, the magnetic wire 10 outputs a pulse (voltage) with a polarity depending on the change in a direction of a magnetic field that is generated by this rotation. The magnet polarity determination unit 14 is provided at a predetermined relative position for the magnetic wire 10, and senses the polarity of the magnet 20 at the placement position thereof.

In FIG. 9, a direction parallel to the rotation axis of the magnet 20 (a rotation axis direction) is the Z axis, and a longitudinal direction of the magnetic wire 10 is the X axis. The magnetic wire 10 may be arranged as follows. The magnetic wire 10 may have one end 51 of the magnetic wire 10 in a longitudinal direction that is arranged in an outer edge region 24 of the magnet 20, viewing from the rotation axis direction of the magnet 20. In FIG. 9, a dotted line that is extended in the Z axis direction from the one end 51 of the magnetic wire 10 to the outer edge region 24 of the magnet 20 is shown. In addition, the magnetic wire 10 may be arranged, in a direction orthogonal to the rotation axis of the magnet 20 (the X axis direction in FIG. 9), such that a central point 52 of a longitudinal axis of the magnetic wire 10 is positioned further outside than the outer edge end 25 of the magnet 20. In FIG. 9, a dotted line that is extended in the Z axis direction from the central point 52 of the magnetic wire 10 to further outside than the outer edge end 25 of the magnet 20 is shown. In addition, in relation to the magnet 20 of a ring shape, an end portion of the magnetic wire 10 (the one end 51 in FIG. 9) may be arranged to overlap with a region occupied by the magnet 20, viewing from the rotation axis direction of the magnet 20. In other words, the end portion of the magnetic wire 10 may be arranged to be positioned in a region between the inner diameter and the outer diameter of the magnet 20, viewing from the rotation axis direction of the magnet 20. In addition, another end 53 of the magnetic wire 10 in the longitudinal direction may be arranged to be positioned on a straight line that passes through the rotation axis of the magnet 20 and that is extended toward the opposite direction of the rotation axis. In other words, the rotation axis of the magnet 20, the one end 51 of the magnetic wire 10, and the another end 53 of the magnetic wire 10 may be arranged on a straight line, viewing from the rotation axis direction of the magnet 20. In addition, in the rotation axis direction of the magnet 20, the magnetic wire 10 may be installed in a space that is upper than the upper surface of the magnet 20 or lower than the lower surface of the magnet 20. Note that the one end 51 and the another end 53 of the magnetic wire 10 may be a point at the center of the end portion of the magnetic wire 10 in a direction perpendicular to the longitudinal direction of the magnetic wire 10 (an axial direction in FIG. 9).

The magnet polarity determination unit 14 may be arranged as follows. The magnet polarity determination unit 14 may be arranged to overlap with the outer edge region 24 of the magnet 20 viewing from the rotation axis direction of the magnet 20. In FIG. 9, a dotted line that is extended in the Z axis direction from the center of the magnet polarity determination unit 14 to the outer edge region 24 of the magnet 20 is shown. In addition, in relation to the magnet 20 of a ring shape, the magnet polarity determination unit 14 may be arranged to overlap with a region occupied by the magnet 20, viewing from the rotation axis direction of the magnet 20. In other words, the end portion of the magnet polarity determination unit 14 may be arranged to be positioned in a region between the inner diameter and the outer diameter of the magnet 20, viewing from the rotation axis direction of the magnet 20. In addition, the magnet polarity determination unit 14 may be integrated into one integrated circuit (IC chip) together with the calculation unit 16. In addition, the magnet polarity determination unit 14 may be arranged at a position 45 degrees or 135 degrees (each including adjustment about ±10 degrees) from a line segment (corresponding to a reference line of the angle in FIG. 8A) connecting the rotation axis to the central portion of the magnetic wire 10, viewing from the rotation axis direction of the magnet 20. In addition, in the rotation axis direction of the magnet 20, the magnet polarity determination unit 14 may be installed in a space that is upper than the upper surface of the magnet 20 or lower than the lower surface of the magnet 20. Also at this time, the magnet polarity determination unit 14 may be arranged, in relation to the magnetic wire 10 and in the rotation axis direction of the magnet 20, in a space on the same side (a space that is closer to the positive side in the Z axis than the magnet 20 in FIG. 9) around the magnet 20, or may be arranged in a space on the opposite side (a space that is closer to the negative side in the Z axis direction than the magnet 20 in FIG. 9).

While the present invention has been described by way of the embodiments, the technical scope of the present invention is not limited to the above-described embodiments. It is apparent to persons skilled in the art that various alterations or improvements can be made to the above described embodiments. It is also apparent from the description of claims that the embodiments added with such alterations or improvements can be included in the technical scope of the present invention.

The operations, procedures, steps, and stages of each process performed by an apparatus, system, flowchart, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, specification, and drawings, it does not necessarily mean that the process must be performed in this order.

What is claimed is:

1. A rotation speed detection apparatus comprising:
a magnetic wire in which an alternating magnetic field of two or more cycles per single rotation is provided in an axial direction in accordance with a rotation operation of a rotator, the magnetic wire outputs a pulse of a polarity depending on a change in a direction of a magnetic field;
a magnet polarity determination unit that determines, at a predetermined relative position in relation to the magnetic wire, a polarity of a magnet that forms the alternating magnetic field and that is included in the rotator; and
a calculation unit that calculates a count value by counting a segment in a circumferential direction of the rotator, wherein the calculation unit calculates the count value, based on a polarity of the magnet of the rotator acquired last time, a polarity of the pulse of this time, and a polarity of the magnet of the rotator at a time the pulse of this time is generated, and without using a polarity of the pulse of last time.

2. The rotation speed detection apparatus according to claim 1, wherein
if the calculation unit is driven by the pulse to start a calculation of the count value, the calculation unit senses, based on the polarity of the magnet of the rotator acquired last time, the polarity of the pulse of this time, and the polarity of the magnet of the rotator at a time the pulse of this time is generated, that another of the segment that is adjacent to the segment opposite to the magnetic wire at a time the pulse was generated last time is moved to a position opposite to the magnetic wire at a time the pulse is generated this time.

3. The rotation speed detection apparatus according to claim 2, comprising a storage unit that integrates the count value calculated by the calculation unit to store the integrated count value as an integrated value.

4. The rotation speed detection apparatus according to claim 3, wherein the calculation unit differentiates, depending on whether or not the polarity of the magnet of the rotator of last time and the polarity of the magnet of the rotator of this time match, the count value for at least one polarity of the pulse of this time.

5. The rotation speed detection apparatus according to claim 4, wherein when the polarity of the magnet of the rotator of the last time is the same as the polarity of the magnet of the rotator of this time, the calculation unit outputs the count value at which the integrated value is maintained, and
when the polarity of the magnet of the rotator of the last time and the polarity of the magnet of the rotator of this time are different from each other, the calculation unit outputs the count value at which the integrated value is decreased or increased.

6. The rotation speed detection apparatus according to claim 5, wherein the calculation unit differentiates a sign of the count value depending on whether or not the polarity of the magnet of the rotator of this time and the polarity of the pulse of this time match.

7. The rotation speed detection apparatus according to claim 1, wherein the magnetic wire is arranged to output the pulse when a boundary of a magnetization of the rotator is deviated from an opposite position.

8. The rotation speed detection apparatus according to claim 7, wherein the magnetic wire is extended in a direction that intersects with a tangential line of the rotator.

9. The rotation speed detection apparatus according to claim 1, wherein
the magnet polarity determination unit is a magnetic sensor, and
the magnetic sensor is arranged not to face any boundary of a magnetization of the rotator when the magnetic wire and the boundary of the magnetization of the rotator are arranged at a position to face each other.

10. The rotation speed detection apparatus according to claim 9, wherein
the magnetic sensor is arranged to have a greatest distance from the boundary of a magnetization of the rotator when the magnetic wire and the boundary of the magnetization of the rotator are arranged at a position to face each other.

11. The rotation speed detection apparatus according to claim 10, wherein the rotator is magnetized to four poles.

12. The rotation speed detection apparatus according to claim 11, wherein the magnetic sensor is arranged in a range of 45±10 degrees or 135±10 degrees from the magnetic wire around a rotation axis of the rotator.

13. The rotation speed detection apparatus according to claim 10, wherein
the rotator is magnetized to n pole, and
the magnetic sensor is arranged in a range of ±40/n degrees around any of θₘ that is an angle from the magnetic wire around a rotation axis of the rotator, wherein θₘ =±180 ×m/n note that m is any odd number less than n.

14. A rotation speed detection system comprising:
the rotation speed detection apparatus according to claim 1; and
the rotator.

15. A rotation speed calculation apparatus that calculates a count value by counting a segment in a circumferential direction of a rotator, based on an output of a magnetic wire and a magnet polarity determination unit, wherein
the magnetic wire is provided with an alternating magnetic field of two or more cycles per single rotation in an axial direction in accordance with a rotation operation of the rotator, and outputs a pulse of a polarity depending on a change in a direction of a magnetic field;
the magnet polarity determination unit determines, at a predetermined relative position in relation to the magnetic wire, a polarity of a magnet that forms the alternating magnetic field and that is included in the rotator; wherein the rotation speed calculation apparatus calculates the count value, based on a polarity of the magnet of the rotator acquired last time, a polarity of the pulse of this time, and a polarity of the magnet of the rotator at a time the pulse of this time is generated, and without using a polarity of the pulse of last time.

16. A rotation speed detection method comprising:
acquiring a polarity of a pulse of a magnetic wire in which an alternating magnetic field of two or more cycles per single rotation is provided in an axial direction in accordance with a rotation operation of a rotator, the polarity of the pulse being output by the magnetic wire depending on a change in a direction of a magnetic field;
acquiring, at a predetermined relative position in relation to the magnetic wire, a polarity of a magnet that forms the alternating magnetic field and that is included in the rotator; and
calculating a count value by counting a segment in a circumferential direction of the rotator, based on a polarity of the magnet of the rotator acquired last time, a polarity of the pulse of this time, and a polarity of the magnet of the rotator at a time the pulse of this time is generated, and without using a polarity of the pulse of last time.

17. The rotation speed detection apparatus according to claim 2, wherein the magnetic wire is arranged to output the pulse when a boundary of a magnetization of the rotator is deviated from an opposite position.

18. The rotation speed detection apparatus according to claim 3, wherein the magnetic wire is arranged to output the pulse when a boundary of a magnetization of the rotator is deviated from an opposite position.

19. The rotation speed detection apparatus according to claim 4, wherein the magnetic wire is arranged to output the pulse when a boundary of a magnetization of the rotator is deviated from an opposite position.

20. The rotation speed detection apparatus according to claim 5, wherein the magnetic wire is arranged to output the pulse when a boundary of a magnetization of the rotator is deviated from an opposite position.
